(19) United States
(12) Patent Application Publication
(10) Pub. No.: US 2011/0266148 A1
(43) Pub. Date: Nov. 3, 2011

(54) TARGET BASE AND SPUTTERING APPARATUS USING SAME

(75) Inventor: SHAO-KAI PEI, Tu-Cheng (TW)

(73) Assignee: HON HAI PRECISION INDUSTRY CO., LTD., Tu-Cheng (TW)

(21) Appl. No.: 12/949,806

(22) Filed: Nov. 19, 2010

(30) Foreign Application Priority Data
Apr. 28, 2010 (TW) 99113390

(51) Int. Cl. C23C 14/34

(52) U.S. Cl. 204/298.28

(57) ABSTRACT

A target base includes a fixed carrier, a rotatable carrier, a number of target housings, and a number of target supports. The rotatable carrier is rotatably mounted on the fixed carrier. The target housings are mounted on the fixed carrier around the rotatable carrier, and define receiving spaces adjacent to the rotatable carrier. The target supports are rotatably mounted on the target housings correspondingly. Each target support is able to rotate to be received in the receiving space of a corresponding one of the target housings or to move out of the receiving space.

### BACKGROUND

1. Technical Field

The present disclosure relates to a target base and a sputtering apparatus using the target base.

2. Description of Related Art

Sputtering apparatuses are commonly used to coat films on surfaces of electronic devices, such as mobile phones, and media players. The sputtering apparatuses include chambers for receiving target materials and workpieces. When working, the target materials are ionized by electronic arcs and the sputtered target ions are deposited on the workpieces to form films. Yet, one chamber can only coat one kind of film on the electronic device, and therefore many chambers are required for when multiple layers of different kinds of films are needed.

Thus, what is needed is a target base and a sputtering apparatus which overcome the above mentioned shortcoming.

### BRIEF DESCRIPTION OF THE DRAWINGS

Many aspects of the embodiments can be better understood with reference to the following drawings. The components in the drawings are not necessarily drawn to scale, the emphasis instead being placed upon clearly illustrating the principles of the present disclosure. Moreover, in the drawings, like reference numerals designate corresponding parts throughout the several views.

FIG. 1 is an exploded view of a target base according to an exemplary embodiment.

FIG. 2 is an assembly view of the target base of FIG. 1.

FIG. 3 is a schematic, isometric view of a sputtering apparatus according to the exemplary embodiment.

FIG. 4 is a cross-sectional view, taken along IV-IV line of FIG. 3.

### DETAILED DESCRIPTION

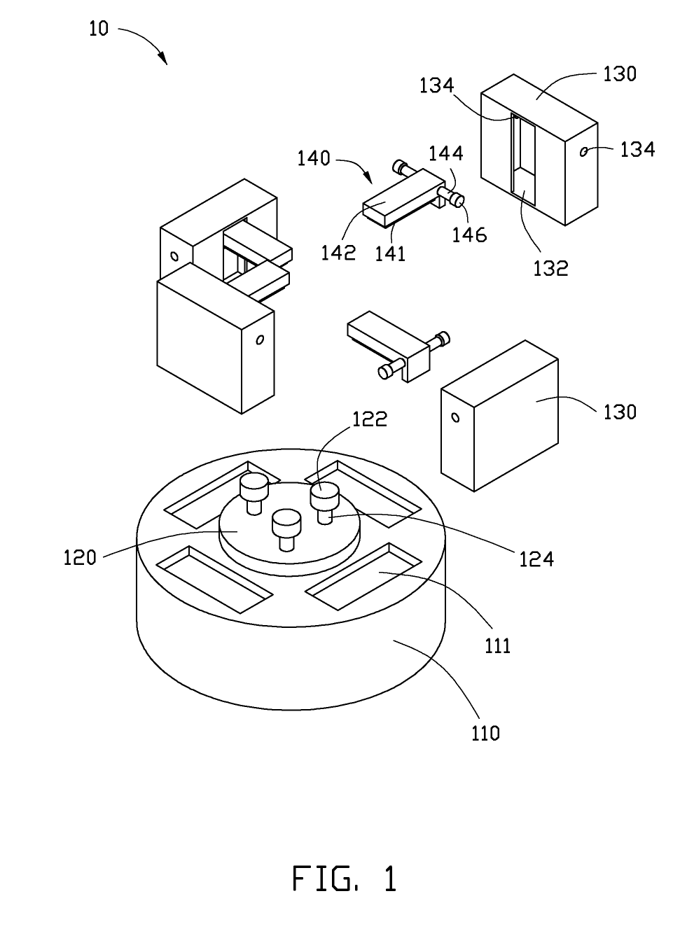

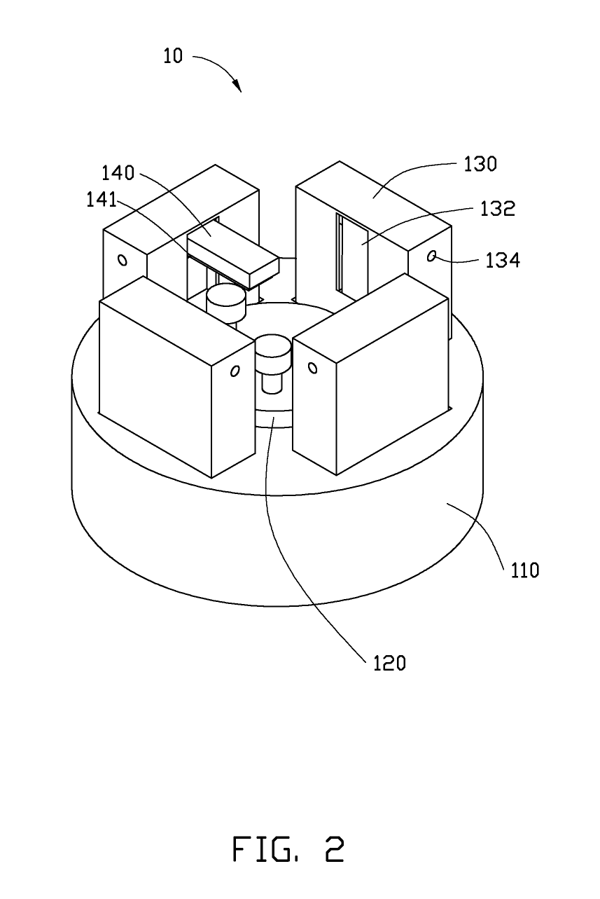

Referring to FIGS. 1 and 2, an exemplary embodiment of a target base 10 includes a fixed carrier 110, a rotatable carrier 120, a number of target housings 130, and a number of target supports 140.

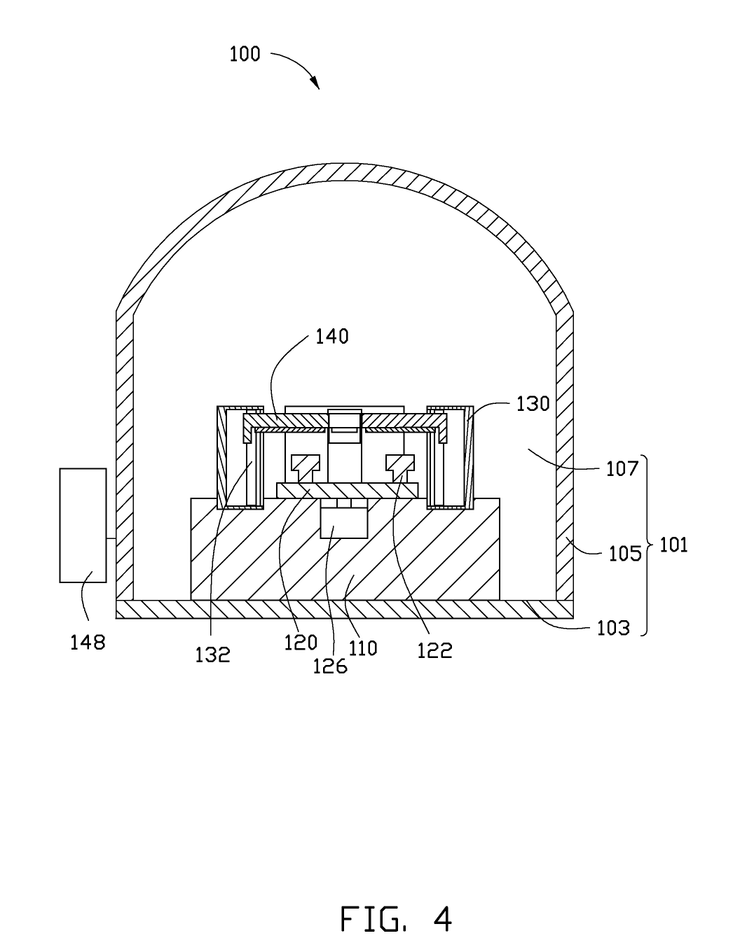

The fixed carrier 110 and the rotatable carrier 120 both are round plates. The rotatable carrier 120 is smaller than the fixed carrier 110. The rotatable carrier 120 is rotatably connected to a centre portion of the fixed carrier 110 by a first actuator 126 (referring to FIG. 4) mounted in the fixed carrier 110.

A number of workpiece supports 122 are rotatably mounted on the rotatable carrier 120 by second actuators 124. The workpiece supports 122 support workpieces (not shown).

The fixed carrier 110 defines a number of grooves 111 around the rotatable carrier 120. The target housings 130 are respectively fixed in the grooves 111. Receiving spaces 132 are defined in the target housings 130 adjacent to the rotatable carrier 120. Two opposite holes 134 are defined on side walls of each receiving space 132.

Each target support 140 includes a pad 142 and a shaft 144 fixed on one end of the pad 142. The shaft 144 plugs into the two opposite holes 134 of a corresponding one of the target housings 130 and is connected with a third actuator 146 which is fixed in the two opposite holes 134. The third actuator 146 drives the shaft 144 to rotate, thus making the target support 140 open from or close to the corresponding target housing 130. A number of target materials 141 are respectively adhered on the pad 142. When the target support 140 open, the target materials 141 are adjacent to the rotatable carrier 120. When the target support 140 close, the target materials 141 are received in the receiving space 132 and are covered by the pad 142. The target materials 141 are varied, that is, one target support 140 carries one kind of target material 141, another target support 140 carries another kind of target material 141.

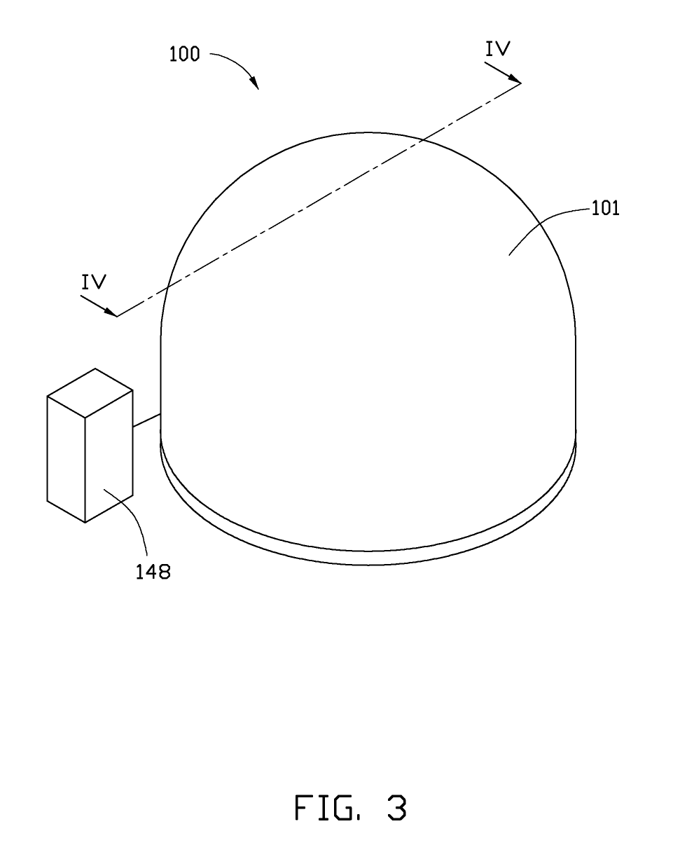

Referring to FIGS. 3 and 4, the target base 10 is used in a sputtering apparatus 100. The sputtering apparatus 100 further includes an enclosure 101 and a controller 148. The enclosure 101 includes a base wall 103 and sidewalls 105. The base wall 103 and the side walls 105 cooperate to define a chamber 107. The target base 10 is received in the chamber 107 and the fixed carrier 110 is fixed on the base wall 103.

The controller 148 is positioned outside the enclosure 101. The controller 148 controls the sputtering apparatus 100. It also controls the first actuator 126, the second actuators 124, and the third actuators 146.

When working, the chamber 107 is vacuumized. The controller 148 controls the third actuators 146 to actuate one of the target supports 140 move to an open state, and the other target supports 140 move to a close state. The controller 148 then controls the first and second actuators 124 and 126 to actuate the rotatable carrier 120 and the workpiece supports 122 to rotate, and ionize the target material 141 carried on the opened target support 140. The other kind of target materials 141 will not be ionized as the pads 142 cover them. The sputtered target ions are deposited on the workpieces to form films. After one kind of film is formed, the corresponding target material 141 is received in the receiving space 132, another kind of target material 141 is exposed in the chamber 107, and the above mentioned steps are then repeated. In this way, different kinds of films are coated in a single chamber 107.

It will be understood that the above particular embodiments are shown and described by way of illustration only. The principles and the features of the present disclosure may be employed in various and numerous embodiments thereof without departing from the scope of the disclosure as claimed. The above-described embodiments illustrate the scope of the disclosure but do not restrict the scope of the disclosure.

What is claimed is:

1. A target base comprising:
a fixed carrier;
a rotatable carrier rotatably mounted on the fixed carrier;
a number of target housings mounted on the fixed carrier and around the rotatable carrier, each target housing defining a receiving space adjacent to the rotatable carrier; and
a number of target supports rotatably mounted on the target housings correspondingly, each target support capable of rotating to be received in the receiving space of a corresponding target housing or to move out of the receiving space.

2. The target base of claim 1, further comprising a number of workpiece supports rotatably mounted on the rotatable carrier.

3. The target base of claim 1, further comprising a first actuator mounted on the fixed carrier and configured for actuating the rotatable carrier to rotate.

4. The target base of claim 2, further comprising a number of second actuators mounted on the rotatable carrier, the second actuators connected to the workpiece supports correspondingly and configured for actuating the workpiece supports to rotate.

5. The target base of claim 1, further comprising a number of third actuators mounted on the target housings, the third actuators connected to the target supports correspondingly and configured for actuating the target supports to rotate respectively.

6. The target base of claim 1, further comprising target materials adhered on the target supports, wherein when the target supports move out of the receiving spaces, the target materials are adjacent to the rotatable carrier, and when the target supports are received in the receiving spaces, the target materials are covered by the target supports.

7. The target base of claim 6, wherein the target supports are adhered by different target materials.

8. The target base of claim 1, wherein each of the target supports is capable of rotating independently.

9. A sputtering apparatus comprising:
an enclosure defining a chamber; and
a target base received in the chamber, comprising:
a fixed carrier;
a rotatable carrier rotatably mounted on the fixed carrier;
a number of target housings mounted on the fixed carrier and around the rotatable carrier, each target housing defining a receiving space adjacent to the rotatable carrier; and
a number of target supports rotatably mounted on the target housings correspondingly, each target support capable of rotating to be received in the receiving space of a corresponding target housing or to move out of the receiving space.

10. The sputtering apparatus of claim 9, wherein the target base further comprises a number of workpiece supports rotatably mounted on the rotatable carrier.

11. The sputtering apparatus of claim 9, wherein the target base further comprises a first actuator mounted on the fixed carrier, and configured for actuating the rotatable carrier to rotate.

12. The sputtering apparatus of claim 10, wherein the target base further comprises a number of second actuators mounted on the rotatable carrier, the second actuators are connected to the workpiece supports correspondingly and configured for actuating the workpiece supports to rotate.

13. The sputtering apparatus of claim 9, wherein the target base further comprises a number of third actuators mounted on the target housings, the third actuators are connected to the target supports correspondingly and configured for actuating the target supports to rotate respectively.

14. The sputtering apparatus of claim 9, wherein the target base further comprises target materials adhered on the target supports, when the target supports move out of the receiving spaces, the target materials are adjacent to the rotatable carrier, and when the target supports are received in the receiving spaces, the target materials are covered by the target supports.

15. The sputtering apparatus of claim 14, wherein the target supports are adhered by different target materials.

16. The sputtering apparatus of claim 9, wherein each of the target supports is capable of rotating independently.
